(19) United States
(12) Patent Application Publication
(10) Pub. No.: US 2026/0259275 A1
(43) Pub. Date: Sep. 3, 2026

(54) DETERMINING THE STATE OF HEALTH OF BATTERIES WITH DYNAMIC DIAGNOSTIC STRESS PROFILE

(71) Applicant: TWAICE Technologies GmbH, München (DE)

(72) Inventors: Stefan GRUBWINKLER, Landshut (DE); Kilian KINK, Neufahrn (DE); Jonas KEIL, München (DE); Michael BAUMANN, München (DE)

(21) Appl. No.: 18/657,001

(22) PCT Filed: Nov. 11, 2022
(86) PCT No.: PCT/EP2022/081584

§ 371 Date: May 7, 2024

(30) Foreign Application Priority Data
Nov. 11, 2021 (DE) 10 2021 129 351.0

(51) Int. Cl. G01R 31/392; G01R 31/367; G01R 31/3842

(52) U.S. Cl. CPC G01R 31/392; G01R 31/367; G01R 31/3842

(57) ABSTRACT

Techniques are described to determine the health status of a battery based on a dynamically adapted diagnostic stress profile.

### TECHNICAL FIELD

Various examples of the disclosure relate to techniques for determining the state of health of rechargeable batteries.

### BACKGROUND

Electric vehicles use rechargeable traction batteries. As batteries age, the health of the batteries may decline. This leads to a decrease in capacity of the traction batteries. This affects the reliability of the operation of the electric vehicle.

It may therefore be desirable to determine the state of health of traction batteries. Various techniques for determining the state of health are known. Such techniques collect measurement data and determine the state of health based on the measurement data. Many of these techniques require a comparatively long time to complete a corresponding diagnosis. For example, a method is known from US2019170827A1 wherein at least two complete charging processes are required in practice. In the case of vehicles, a longer drive is necessary between two charging processes, so that determining the state of health takes a long period of time due to the size of the battery.

For example, Stroe, Daniel I., et al. “Diagnosis of lithium-ion batteries state-of-health based on electrochemical impedance spectroscopy technique.” 2014 IEEE Energy Conversion Congress and Exposition (ECCE). IEEE, 2014 describes a laboratory technical method that requires the use of special measuring equipment for impedance spectroscopy.

For example, US2019170827A1 describes a method for determining the state of health (SOH) by repeatedly measuring the voltage during a charging process and using a Kalman filter. The process requires many measurement data and is therefore slow.

CN201911402190.9A describes a method to determine the SOH particularly fast. However, it was observed that the accuracy of the method is reduced. The same applies to US 2007/0236225 A1.

### ABSTRACT

Thus, there is a need for improved techniques to determine the state of health of rechargeable traction batteries in electric vehicles as quickly and yet as accurately as possible. There is a need for techniques that enable the state of health of an entire battery pack in electric vehicles without complex measuring devices, such as impedance spectroscopy, for instance by using a communication interface available in repair shops.

This object is achieved by means of the features of the independent claims. The features of the dependent claims define embodiments.

With the techniques described herein, it becomes possible to determine the state of health of a traction battery of an electric vehicle using a partial charging process or a partial discharging process. For example, a test bench equipped with a charger can be used for this purpose. A diagnostic stress profile with variable parameters can be used. This is used to charge or discharge the traction battery. Measurement data that is collected during the application of the diagnostic stress profile, for example by a battery management system (BMS) of the battery, can be collected and recorded via a suitable vehicle interface (e.g., OBD2 interface) with a user terminal (e.g., a computer). The measurement data can be transferred in the cloud to a server. The state of health can then be estimated at the server from the measurement data using an estimation algorithm.

A computer-implemented method comprises obtaining type data and status data of a traction battery of an electric vehicle. The traction battery is connected to a test bench. The method further comprises determining a diagnostic stress profile based on the type data and based on the status data. The diagnostic stress profile comprises several operating blocks. The several operating blocks are associated with different stress scenarios. In addition, the computer-implemented method also comprises activating a test bench to apply the diagnostic stress profile. In this way, measurement data is obtained for a voltage profile and a current profile of a stress process of the traction battery. In addition, the method also comprises determining a state of health estimation of the traction battery based on the measurement data.

A computer program or a computer program product or a computer-readable storage medium comprises program code. The program code can be loaded and executed by a processor. This causes the processor to execute a method. The method comprises obtaining type data and status data of a traction battery of an electric vehicle. The traction battery is connected to a test bench. The method further comprises determining a diagnostic stress profile based on the type data and based on the status data. The diagnostic stress profile comprises several operating blocks. The several operating blocks are associated with different stress scenarios. In addition, the computer-implemented method also comprises activating a test bench to apply the diagnostic stress profile. In this way, measurement data is obtained for a voltage profile and a current profile of a stress process of the traction battery. In addition, the method also comprises determining a state of health estimation of the traction battery based on the measurement data.

A device comprises a processor and a memory. The processor can load program code from the memory and execute it. This causes the processor to execute a method. The method comprises obtaining type data and status data of a traction battery of an electric vehicle. The traction battery is connected to a test bench. The method further comprises determining a diagnostic stress profile based on the type data and based on the status data. The diagnostic stress profile comprises several operating blocks. The several operating blocks are associated with different stress scenarios. In addition, the computer-implemented method also comprises controlling a test bench to apply the diagnostic stress profile. In this way, measurement data is obtained for a voltage profile and a current profile of a stress process of the traction battery. In addition, the method also comprises determining a state of health estimation of the traction battery based on the measurement data.

The features presented above and features that are described below can be used not only in the corresponding explicitly presented combinations, but also in further combinations or in isolation, without departing from the protective scope of the present invention.

### BRIEF DESCRIPTION OF THE FIGURES

FIG. 1 schematically illustrates a device for data processing according to various examples.

FIG. 2 is a flowchart of an exemplary method.

FIG. 3 is a flowchart of an exemplary method.

FIG. 4 shows an exemplary reference dependency of a parameter of a diagnostic stress profile on states of a traction battery.

FIG. 5 is a signal flow diagram illustrating communication between a test bench, a user terminal, a server, and a database according to various examples.

FIG. 6 schematically shows a diagnostic stress profile according to various examples.

### DETAILED DESCRIPTION

The properties, features, and advantages of this invention described above, and the manner in which they are achieved, will become clearer and more easily understood in connection with the following description of the exemplary embodiments, which are explained in more detail in connection with the drawings.

In the following, the present invention is explained in more detail with reference to the drawings with reference to preferred embodiments. In the figures, identical reference numbers denote identical or similar elements. The figures are schematic representations of various embodiments of the invention. Elements depicted in the figures are not necessarily drawn to scale. Rather, the various elements shown in the figures are presented in such a way that the function and general purpose thereof can be understood by one skilled in the art. Connections and couplings between functional units and elements shown in the figures can also be implemented as an indirect connection or coupling. A connection or coupling can be implemented wired or wireless. Functional units can be implemented as hardware, software, or a combination of hardware and software.

Techniques for determining the state of health of a battery are described below. The state of health can, for example, correspond to the capacity of the battery. The state of health could also correspond to the impedance of the battery. Typically, as a battery ages, the capacity of the battery decreases and the impedance of the battery increases.

The techniques described herein enable a particularly rapid and yet reliable determination of the state of health of the battery. The techniques described herein do not require complex measuring equipment.

Therefore, the techniques described herein can be used in particular in connection with traction batteries of electric vehicles connected to a test bench. For example, during a technical suitability test of the electric vehicle, the state of health could be checked on an appropriate test bench. In such applications, it is necessary that the diagnostic time (i.e., the time needed to collect the measurement data based on which the state of health estimation is determined) is not too long in order to reduce the time required per vehicle.

The test stand can charge or, in some examples, discharge the batteries. A corresponding diagnostic stress profile can be used to apply a specific stress to the battery during charging and/or discharging. Corresponding measurement data—which, for example, indicate voltage values and current values—can then be collected and a state of health estimation can be determined based on the measurement data.

The measurement data can therefore comprise a voltage profile and a current profile, i.e., voltage values as a function of time and current values as a function of time, in each case while the diagnostic stress profile is being applied.

As a general rule, it would be conceivable that the current profile and/or the voltage profile are provided averaged over the various battery cells of the battery. Alternatively or additionally, it would also be possible for the current profile and/or the voltage profile to be provided for different battery cells, i.e., voltage and current are indexed in different battery cells. This could make it possible to detect imbalances between the different battery cells and to mark or correct the battery's state of health accordingly.

The measurement data can also contain other information as an alternative or in addition to the voltage profile or current profile. For example, the measurement data could indicate the state of charge of the battery and/or an operating temperature of the battery.

The diagnostic stress profiles used can have several operating blocks, each of which is associated with different stress scenarios for the battery.

Various examples are based on the knowledge that different electrochemical processes in the battery cells of the battery can be differentiated by using different stress scenarios. The voltage profile and the current profile can accordingly comprise characteristic features for the electrochemical processes. This may make it possible to determine the state of health estimation taking into account the various relevant electrochemical processes (and thus particularly accurately).

Some examples of operating blocks are listed in TAB. 1 below.

TABLE 1
Various examples of operating blocks that together can form a stress
profile. In addition, parameters are specified that characterize a corresponding
operating block and in some examples can be determined type-specifically
and state-specifically (details are explained later).

| Operating | | |
|---|---|---|
| block | Explanation | Parameter |
| Rest period | There is no charging or discharging | Duration of the rest phase |
| | during the rest phase. This means that | |
| | no current flow is applied to the battery | |
| | from outside. | |
| | The rest phase can be used to prepare | |
| | a rest voltage measurement. This | |
| | means that the battery can be in a | |
| | relaxed state and then, for example, a | |
| | current pulse can be used to determine | |
| | a value for the rest voltage. | |
| Current | One or more current pulses can be | Duration between current |
| pulse | used here, for example to charge the | pulses |
| | battery suddenly. There could also be | Duration/number of |
| | a sudden increase in current flow. | current pulses |
| | By using current pulses, overvoltages | Plateau duration of the |
| | can be determined. For this purpose, | current pulses |
| | the time behavior of the system | Amplitude of the current |
| | response can be estimated, i.e., for | pulses |
| | instance a time offset between current | |
| | pulse and voltage change. | |
| Constant | In an operating block with constant | Amplitude |
| current flow | current flow, a finite charging current or | Duration |
| | discharging current with constant | |
| | amplitude can be used over an extended | |
| | period of time. | |
| | The charging curve and discharging | |
| | curve for lithium storage batteries differ | |
| | (hysteresis). | |
| | By using the constant current flow, the | |
| | hysteresis effect can be compensated | |
| | for so that the battery voltage | |
| | corresponds to the value on the charging | |
| | or discharging curve. | |
| | In addition, charging with a constant | |
| | current can generate a specific | |
| | difference in charge states. This allows | |
| | a specific charge state to be set by | |
| | charging or discharging the battery. | |
| Variable | In such an operating block, charging or | Amplitude modulation |
| current flow | discharging can be carried out | pattern (shape, frequency, |
| | continuously with a current flow that is | etc.) |
| | either greater or less than 0, although | Duration |
| | the amplitude of the current flow varies. | Amplitude |
| | For example, amplitude modulation | |
| | could be performed with a sinusoidal, | |
| | rectangular, triangular or sawtooth | |
| | amplitude modulation pattern. | |
| | Combinations of different patterns would | |
| | also be possible, even at different | |
| | frequencies. | |

TAB. 2 below represents an example of a diagnostic stress profile.

TABLE 2
An exemplary diagnostic stress profile consisting of a specific
sequence of operating blocks according to TAB. 1.

| Phase | Operating block | Explanation |
|---|---|---|
| I | Rest period | Start of measurement with rest phase to |
| | | determine the open-circuit voltage of the |
| | | battery system and the individual cells/modules |
| II | Constant current | Charging with constant current to compensate |
| | flow | for the hysteresis effect |
| III | Current pulse | Several pulses with rest phases in between for |
| | | determining any overvoltages that occur and for |
| | | determining the time constants of the impulse |
| | | response |
| IV | Rest period | Determination of the rest voltage |
| V | Constant current | SOC difference to phase III |
| | flow | |
| VI | Current pulse | Several pulses with rest phases in between for |
| | | determining any overvoltages that occur and for |
| | | determining the time constants of the impulse |
| | | response |
| VII | Rest period | Rest phase to determine the rest voltage of the |
| | | battery system and the individual cells/modules |

Various examples are also based on the knowledge that the electrochemical processes (e.g., the hysteresis effect, reaching a resting state, etc.) can occur on different time scales and/or with different strengths depending on the type and state of the battery. The electrochemical processes behave differently for different battery types. Different time scales and/or strengths of the electrochemical processes can also be observed for batteries of the same battery type, depending on the state of the battery, for example depending on the temperature or state of charge.

In order to determine a diagnostic stress profile based on this finding, which minimizes the diagnostic time and at the same time records sufficient measurement data to reliably determine the state of health, the diagnostic stress profile to be used is determined based on type data and based on status data of a traction battery of an electric vehicle connected to a test bench. This means that the diagnostic stress profile can be determined on a type-specific and state-specific basis.

The type data is indicative of a type of battery. For example, the type data could indicate a manufacturer, a manufacturer number, a serial number, etc. The type data could be indicative of the cell chemistry of the battery, e.g., specify an electrode material. The type data could, for example, be indicative of a cell geometry. The type data could indicate whether the battery has an active cooling system. The type data can in any case be unchangeable for the lifetime of the battery; this means that the type data can be independent of the current state of the battery.

The state of the battery changes over time. The current status of the battery can be displayed by the status data. For example, the status data could be indicative of a current state of charge (SOC) of the battery, i.e., indicate, for example, the relative charge of the battery in relation to a nominal capacity of the battery. The status data could be indicative of an operating temperature of the battery.

By selecting the diagnostic stress profile based on the type data and the status data, a suitable diagnostic stress profile can be selected. This means that the shortest possible diagnostic stress profile can be selected, i.e., with the shortest possible diagnostic time. Nevertheless, it may be possible to determine the state of health of the battery as accurately as possible using the appropriate diagnostic stress profile.

Based on the diagnostic stress profile, the test bench can then be activated to apply the diagnostic stress profile. The measurement data can be obtained in this way. Based on the measurement data, it is then possible to determine the state of health estimation. As a general rule, different techniques can be used to determine the state of health estimation. This means that different types of estimation algorithms can be used. For example, it is conceivable that an estimation algorithm could comprise a machine-learned model. Examples of machine-learned models include artificial neural networks, regression models, etc. See for example: Roman, Darius, et al. “Machine learning pipeline for battery state-of-health estimation.” Nature Machine Intelligence 3.5 (2021): 447-456. An example of an artificial neural network would be an LSTM network (see e.g. Qu, Jiantao, et al. “A neural-network-based method for RUL prediction and SOH monitoring of lithium-ion battery.” IEEE access 7 (2019): 87178-87191). However, the estimation algorithm does not necessarily have to comprise a machine-learned model. For example, conventionally parameterized models could also be used. Filtering methods could be used, for example a Kalman filter or a method for adapting pre-defined dependencies. Example techniques are described e.g. in: Andre, Dave, et al. “Advanced mathematical methods of SOC and SOH estimation for lithium-ion batteries.” Journal of power sources 224 (2013): 20-27. In various examples, a single-stage estimation algorithm can be used that directly estimates the state of health based on the measurement data. On the other hand, it would also be conceivable to estimate one or more values for one or more battery parameters in a first stage (for example, to parameterize an equivalent circuit model). Then, in a 2nd stage, the state of health can be estimated based on one or more values. In such a scenario, the battery can therefore be modeled using a physical model, such as an equivalent circuit model or a heat dissipation model. See. e.g. Chang, Fengqi, et al. “Modelling and evaluation of battery packs with different numbers of paralleled cells.” World Electric Vehicle Journal 9.1 (2018): 8. It is clear from these explanations that the specific estimation algorithm is not decisive for the techniques described here. In principle, known estimation algorithms can be used.

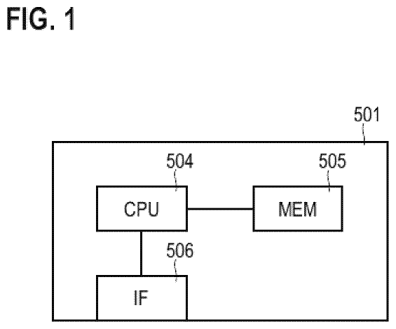

FIG. 1 schematically illustrates a device 501 that may be adapted to perform techniques related to estimating a state of health, such as those described thereto. For example, device 501 could be implemented by a computer. Device 501 could be implemented by a server.

Device 501 comprises a processor 504 and a memory 505. In addition, device 501 also comprises a communication interface 506 through which the processor 504 can communicate with other entities. For example, the processor 504 could activate a test bench connected to an electric vehicle via the communication interface 506 so that the test bench applies a diagnostic stress profile. The processor 504 could receive measurement data via the communication interface 506. Examples of such measurement data would be, for example, a voltage profile or a current profile. Other measurement data could also be obtained, for example a profile relating to the state of charge, i.e., the change in the state of charge as a function of time; and/or a profile relating to the temperature, i.e., the operating temperature of the battery as a function of time. The processor 504 can load program code from the memory 505 and execute it. This causes the processor to perform techniques related to state of health estimation as described herein. For example, the processor may determine a diagnostic stress profile based on type data and status data of a battery. The processor may also estimate the state of health of the battery based on measurement data, for example by executing one or more estimation algorithms.

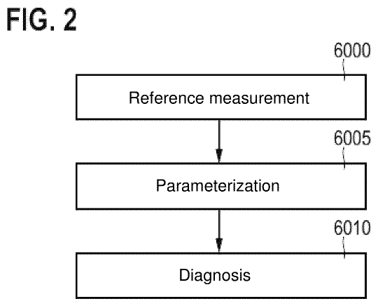

FIG. 2 illustrates a flow chart according to various examples. The flowchart from FIG. 2 shows various phases related to the preparation and use of an estimation algorithm used to estimate a state of health. FIG. 2 also shows various aspects related to the preparation of the determination of the diagnostic stress profile depending on the state and type of traction batteries.

First, one or more reference measurements are carried out in box 6000. The reference measurements can be used to characterize rechargeable traction batteries in electric vehicles. The reference measurements can, for example, quantify certain physical-chemical properties of the traction batteries. For example, reference dependencies between parameters of a diagnostic stress profile and different states of traction batteries could be determined for different types of traction batteries, e.g., using such a quantification of physical-chemical properties.

Examples of physical-chemical properties that can be quantified as part of the reference measurements would be, for example: Hysteresis voltage; pulse response of the battery; rest voltage. Such physical-chemical properties can, for example, be determined for different states of the battery, that is, for example, for different states of charge or different operating temperatures, etc.

It is possible that the reference measurements also comprise the application of a reference diagnostic stress profile. In this manner, training measurement data can be obtained. The reference diagnostic stress profile can then serve as a template for a diagnostic stress profile, which is used during the inference phase to record corresponding measurement data.

The reference measurements can be used to determine a ground truth regarding the state of health of the traction batteries. This means that the reference measurements can be used to determine, for example, the capacity or impedance. The reference measurements may be different from the measurement in connection with the application of the diagnostic profile; for example, laboratory procedures to determine the state of health may be used in connection with the reference measurement.

Box 6005 contains the parameterization of an estimation algorithm that can be used to determine the state of health estimation of traction batteries. This can be based on the reference measurements. Based on the reference measurements, training measurement data can be obtained and used to parameterize the estimation algorithm in box 6005. Based on the reference measurements, ground truth for the state of health can also be determined. For example, the state of health of a battery could be determined using the reference measurements and assigned to corresponding training measurement data. For example, the reference measurements could be carried out in a laboratory. Typically, such laboratory measurements can determine the state of health of batteries with high accuracy, for example using electrical impedance spectroscopy, etc.

For example, box 6005 can comprise training for machine-learned algorithms. For example, back propagation techniques (gradient descent) could be used to determine weights of an artificial neural network.

Manual parameterization could also be done.

Regardless of the specific mode of parameterization, box 6005 can be used to check that the output of the estimation algorithm (i.e., the state of health estimation) matches the ground truth as closely as possible.

A diagnosis can then be carried out in box 6010. This means that the state of health estimation can be performed without any corresponding ground truth being available. Box 6010 is also called the inference phase. One or more estimation algorithms that were parameterized in box 6005 can be used for this purpose.

In principle, it would be conceivable that both box 6005 and box 6010 are executed by a device such as device 501 (see FIG. 1). However, it would also be conceivable that different devices are used to run box 6005 and box 6010.

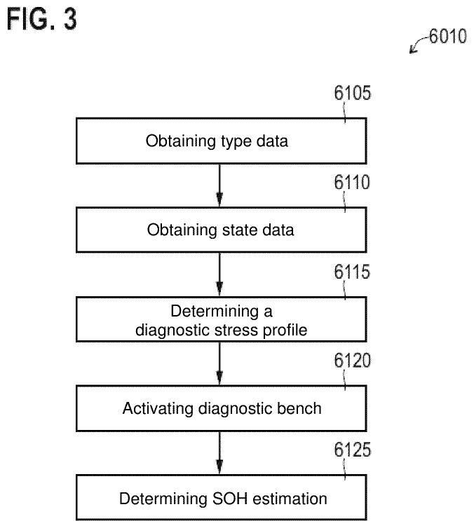

Next, details related to box 6010 are shown in FIG. 3 described. FIG. 3 is a flowchart of an exemplary method. FIG. 3 is a flowchart of a method for determining a state of health estimation of a battery. FIG. 3 concerns the inference phase, i.e., rules for determining the diagnostic stress profile as a function of type data and status data are already known, for example based on the reference measurements from box 6000. In addition, an estimation algorithm is available that is parameterized and can be used to determine the state of health estimation based on measurement data.

For example, the method of FIG. 3 could be executed by the device 501 of FIG. 1. In particular, the method of FIG. 3 could be executed by a server.

Box 6105 contains type data for a traction battery of an electric vehicle. The electric vehicle is connected to a test bench. The type data can be read out or information indicative of the type data can be read out via a data connection between the test stand and the traction battery (for example with a traction battery management system). The test bench can then transmit the type data to the server. The type data can identify a type of traction battery. Certain type characteristics of the traction battery that are not directly dependent on operation can be indicated by the type data, e.g., serial number, manufacturer identification, cell geometry, number of cells, etc.

Box 6110 contains status data from the traction battery of the electric vehicle. For example, the status data can be obtained from the management system of the traction battery via the data connection between the test bench and the traction battery. The status data can describe a current status of the traction battery. For example, the status data could describe the state of charge of the traction battery (i.e., indicate the SOC). The status data could, for example, indicate an operating temperature of the traction battery.

In box 6115, a diagnostic stress profile is then determined based on the type data and also based on the status data. The diagnostic stress profile comprises several operating blocks, the operating blocks being associated with different stress scenarios. Examples of operating blocks were mentioned above in connection with TAB. 1 described. An exemplary diagnostic stress profile was explained in TAB. 2.

This means that the diagnostic stress profile can be specifically adapted to the respective type of traction battery and can also be specifically adapted to the respective state of the traction battery. This enables a particularly short diagnostic stress profile to be determined, meaning that the diagnostic stress profile can comprise as few operating blocks as possible and/or the operating blocks are particularly short. At the same time, the state of health can be determined particularly precisely by tailoring the diagnostic stress profile to the type and state of the battery.

The diagnostic stress profile can be determined based on reference dependencies between parameters of the diagnostic stress profile and the status data and/or the type data. Such reference dependencies can be determined based on the reference measurements (compare FIG. 2: Box 6000).

The diagnostic stress profile can be determined in such a way that the diagnostic time is minimized. In general terms, the diagnostic stress profile can be determined taking into account the duration of the diagnostic stress profile.

The diagnostic stress profile can be determined to maximize the accuracy of the state of health estimation. In general terms, the diagnostic stress profile can be determined taking into account the accuracy of the state of health estimation.

In box 6120, the test bench is then activated to apply the diagnostic stress profile. Relevant information is obtained from box 6115. For example, certain parameters can be transmitted to the test bench, such as a sequence of operating blocks and corresponding parameter values for properties of the operating blocks, such as duration, current amplitudes, etc. If different candidate diagnostic stress profiles are already stored on the test bench, an index of the candidate diagnostic stress profile to be activated can also be transmitted to the test bench.

Then, in connection with activating the test bench, corresponding measurement data is also obtained to obtain the voltage profile and the current profile of the stress process of the traction battery associated with the diagnostic stress profile. As an alternative or in addition to the voltage profile and the current profile, a profile of the operating temperature and/or a profile of the state of charge could also be obtained. The measurement data can be generated by a battery management system and transmitted to the test bench.

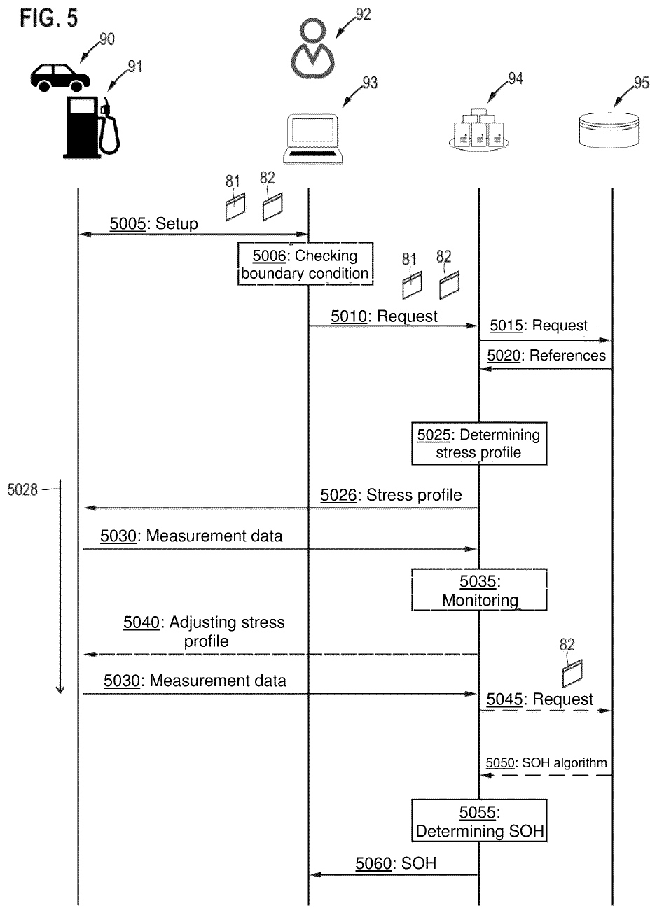

In some examples, the measurement data may be obtained continuously, that is, while applying the diagnostic stress profile. In other examples, it would also be conceivable for the measurement data to be obtained only after the diagnostic stress profile has been completed. If the measurement data is received continuously, it would be conceivable to adjust the diagnostic stress profile before the end of the diagnostic time, i.e., it would be possible to react directly to certain signatures in the measurement data and shorten or lengthen the diagnostic stress profile, for example. Corresponding aspects are explained later in connection with FIG. 5: Box 5035.

Based on such measurement data, the state of health estimation of the traction battery can then be determined in box 6125. One or more estimation algorithms that have been previously parameterized can be used for this purpose (see FIG. 2: Box 6005).

As explained above, a predefined set of rules can be used to determine the diagnostic stress profile. The predefined set of rules could, in a simple variant, be determined by expert knowledge. Two more examples are shown in TAB. 3.

TABLE 3
Two exemplary strategies to determine the diagnostic stress profile.

| How are the rules for | |
|---|---|
| determining the diagnostic | |
| stress profile determined? | Explanation |
| According to the | The set of rules can be obtained in connection with the |
| parameterization of the | parameterization of the estimation algorithm, see FIG. |
| estimation algorithm | 2: Box 6005. To parameterize the estimation algorithm, |
| | training measurement data can be used, which are |
| | recorded based on a reference diagnostic stress |
| | profile. A diagnostic stress profile can then be used which |
| | is as similar as possible to the reference diagnostic |
| | stress profile. This means that the reference measurement |
| | is recreated as accurately as possible in the |
| | inference phase. |
| | This means that a dependency between parameters of |
| | the diagnostic stress profile and the state data and the |
| | type data can be selected in such a way that the diagnostic |
| | stress profile matches the reference diagnostic |
| | stress profile used to record the training measurement |
| | data with which the estimation algorithm was |
| | parameterized as closely as possible. |
| | Such techniques are based on the knowledge that the |
| | parameterization of the estimation algorithm is |
| | adapted to a specific measurement scenario and that |
| | a reproduction of the measurement scenario typically |
| | enables particularly accurate results. This is |
| | particularly true for machine-learned models, such as |
| | artificial neural networks. For machine-learned models, |
| | the accuracy of the prediction is particularly high when |
| | the input data during inference is comparable to the |
| | input data during training. |
| Based on the chemical- | The set of rules can be determined based on the |
| physical properties of | physical-chemical properties of the battery, wherein |
| the battery | these chemical-physical properties are determined, for |
| | example, using the reference measurements or based on |
| | literature knowledge. |
| | For example, basic dependencies between physical |
| | and chemical states of the battery can be recorded |
| | using reference measurements. |
| | The advantage of such an approach is that statements |
| | can also be made about areas of the condition data or |
| | type data for which no reference measurements have |
| | been recorded. This means that, for example, |
| | interpolation can be carried out in order to determine a |
| | suitable diagnostic stress profile for a specific value |
| | of the status data. |
| | For example, reference measurements could be used |
| | to determine that a particular battery type has a |
| | particularly strong hysteresis voltage. It may then be |
| | necessary to design the diagnostic stress profile |
| | accordingly in order to compensate for the strong |
| | hysteresis voltage. This may result in an extended |
| | diagnostic time for this battery type. However, there may |
| | not be a correspondingly strong hysteresis voltage for a |
| | different battery type and the diagnosis time can then be |
| | reduced for such a battery type. |
| | The reference measurements can also be used to |
| | parameterize the estimation algorithm (see FIG. 2: Box |
| | 6005). |

Specific implementations of the strategies from TAB. 3 are described below.

For example, it would be conceivable for the operating blocks of the diagnostic stress profile to be selected from a large number of predefined operating blocks. This means that, using the modular principle, different operating blocks, each of which has been predefined, can be put together to form the diagnostic stress profile.

This has the advantage that individual parameters of the various operating blocks can be predefined and only the predefined operating blocks can be strung together. In particular, predefined operating blocks can be used, for which training measurement data has already been recorded during the parameterization of the estimation algorithm (see FIG. 2: Box 6005). In other words, comparable stress scenarios can be used for the actual diagnosis in box 6010 and the parameterization in box 6005. This enables a high level of accuracy to be achieved in connection with the determination of the state of health; nevertheless, different boundary conditions, for example batteries of different types or in different states, can be taken into account.

In addition to selecting the various operating blocks, determining the diagnostic stress profile in accordance with TAB. 3: Scenario 1 can also include determining the sequence of the several operating blocks. In other words, this means that the sequence and/or the number of times different operating blocks are used in the diagnostic stress profile can be varied. It may also be possible to parameterize one or more parameters of at least one operating block of the several operating blocks. For example, in connection with TAB. 1 sets out various parameters for the different operating blocks above. Such parameters can therefore concern, for example Duration of the corresponding operating block; Discharge rate or charge rate (also referred to as C-rate) of a corresponding discharge current or charge current; Amplitude of current pulses; etc.

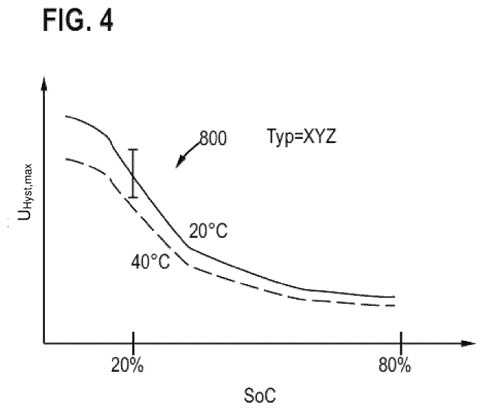

Next, in connection with FIG. 4, a predefined reference dependency is explained, which can be taken into account when determining the diagnostic stress profile. For example, it would be possible to parameterize one or more parameters of the at least one operating block based on such a dependency.

FIG. 4 shows a dependency 800 of the maximum possible hysteresis voltage on the state of charge of the battery for a specific battery type. This dependency 800 characterizes a chemical-physical property of the respective battery type. This dependency 800 is shown for several temperatures (solid and dashed lines).

The maximum possible hysteresis voltage influences the time required to reach the resting voltage characteristic in the charging direction.

The maximum possible hysteresis voltage is therefore directly proportional to the duration of an operating block of the diagnostic stress profile with constant current flow (see TAB. 1). Therefore, FIG. 4 a dependency between the corresponding parameter of the diagnostic stress profile and the corresponding status data (SOC, temperature) and type data (battery type “XYZ”).

FIG. 4 therefore shows that smaller maximum hysteresis voltages are expected for higher temperatures and that the time required to reach this maximum voltage can therefore be reduced. FIG. 4 also shows that smaller maximum hysteresis voltages are expected for larger charge states, which means that the time required to reach the target voltage can also be reduced. This means that depending on the state of charge and temperature of a battery of the corresponding type—the state of charge and temperature are provided via the status data—and taking into account the dependency from FIG. 4, the duration of the charging phase with constant current flow can be adjusted.

In FIG. 4 shows only an example of a dependency between parameters of the diagnostic stress profile and state or type data. Further examples of such dependencies are summarized below in TAB. 4 below.

TABLE 4
Various examples of dependencies between parameters (more precisely: parameter
values) of the diagnostic stress profile and status data; these dependencies
are different for different batteries. As a general rule, such predefined dependencies
can be determined based on reference measurements (see box 6000 in FIG. 2). The
different examples can be considered individually or in combination.

| Dependency | Details |
|---|---|
| Hysteresis voltage/duration | When the state of charge changes, a certain hysteresis |
| of charging phase - State of | voltage can occur. This hysteresis voltage can |
| charge, battery type and/or | cause a subsequent measurement of the resting voltage |
| temperature (see FIG. 4) | to be distorted. Accordingly, it may be necessary |
| | to provide compensation for the hysteresis voltage. |
| | This hysteresis voltage differs depending on the |
| | battery type. The hysteresis voltage changes depending |
| | on the state of charge of the battery. In addition, the |
| | hysteresis voltage changes depending on the cell |
| | temperature. |
| | By taking this dependency into account, the diagnosis |
| | time can be chosen to be as long as necessary |
| | but as short as possible. |
| State of charge difference - | Depending on the battery type, it may be necessary |
| battery type | to provide a different offset between the states of |
| | charge to obtain significant results, it may be |
| | sufficient for some battery types to use a comparatively |
| | small offset, for example of 5 percentage points, while |
| | for other battery types a larger offset between the |
| | states of charge is necessary. A charging phase can |
| | then be shortened or extended accordingly. |
| Dynamic response - battery | As discussed above in connection with TAB. 2 above, |
| type, state of charge and/or | measuring the dynamic response (e.g., impulse |
| temperature | response) of the battery to current pulses at different |
| | states of charge can be helpful in detecting |
| | overvoltages. The duration of the current pulses and the |
| | duration of the subsequent pause depends on the |
| | battery type, the current state of charge and the |
| | temperature of the cell. |

As a general rule, a respective expected value for the accuracy of the state of health estimation (i.e., a confidence value) could also be taken into account within the framework of such dependencies (see TAB. 4). This means that the diagnostic stress profile is determined taking into account the respective expected value for the accuracy of the state of health estimation. For example, a tolerance range is given in FIG. 4 for the 20% stress status. This tolerance range could, for example, be associated with a predefined interval for the expected value of the accuracy of the state of health estimation. For example, by choosing the duration of the corresponding operating block within the tolerance range, an accuracy of at least 80% of an optimal accuracy (indicated by the solid line) could be obtained. In this way, tolerances can be provided which can be exploited, for example, if a further reduction in the diagnosis time is desired.

As a general rule, such an expected value for the accuracy of the state of health estimation could be obtained from the reference measurements for corresponding battery types. For example, an estimation algorithm could be tested with the help of measurement data from reference measurements and thus the accuracy range/dispersion of the algorithms could be specified. There are also estimation methods (Kalman filters, neural networks) that inherently provide an accuracy of the estimate.

In such scenarios, it is therefore possible for the diagnostic stress profile to be determined both taking into account the duration of the diagnostic stress profile and also taking into account the accuracy of the diagnostic stress profile. For example, by leveraging tolerances, the time duration can be specifically increased or the accuracy can be specifically reduced.

Based on TAB. 4, it can be seen that scenarios can occur in which there are conflicting objectives. For example, in order to achieve the highest possible accuracy in estimating state of health, it may be desirable to provide certain blocks of operation or to parameterize blocks of operation in a certain way; whereas in order to achieve the shortest possible diagnosis time, it may be desirable not to provide these blocks of operation or to parameterize them differently. As a general rule, it would be possible for the diagnostic stress profile to be determined using iterative numerical optimization. This can have an objective function that, on the one hand, penalizes longer diagnosis times and, on the other hand, penalizes lower levels of accuracy in estimating the state of health. This means that the conflict of objectives can be resolved by using iterative numerical optimization by aiming for both a particularly short diagnosis time and the highest possible accuracy in estimating the state of health. Iterative numerical optimization could be implemented, for example, by a gradient descent method, a simplex optimization algorithm, or genetic algorithms. The target function can be formulated taking into account predefined dependencies 800, as explained above in connection with FIG. 4 or TAB. 4 above.

Using the above techniques, it is therefore possible to shorten the diagnosis time and at the same time improve the quality of the estimated state of aging by determining the diagnostic stress profile on a type-specific and state-specific basis. Overall, it was found that high quality estimates of the state of aging can be achieved even if the battery is partially charged or partially discharged.

For example, using the techniques described herein, it may be unnecessary to fully discharge or fully charge the battery when applying the diagnostic stress profile. Instead, the battery can be partially discharged or partially charged. This means that the state of charge (SOC) can change by a few percentage points, in particular by less than 100 percentage points. For example, the state of charge could be changed by less than 15 percentage points, i.e. charging could be carried out from 40% SOC to 55% SOC (this is referred to as a charging stroke, ASOC). This can reduce the diagnosis time. In general, the charging stroke could be less than or equal to 50 percentage points, optionally less than or equal to 20 percentage points, and optionally less than or equal to 15 percentage points.

Such a shortened diagnosis time enables specific application scenarios. For example, in the context of a technical suitability test of motor vehicles—where the time per vehicle is typically very limited in order to check enough vehicles—the state of health of the traction batteries can be estimated when the vehicles are connected to a test bench. A corresponding application scenario is shown below in connection with FIG. 5 described. FIG. 5 is a signal flow diagram illustrating communication between a test bench 91 to which an electric motor vehicle 90 is connected, a user terminal 93 (e.g., a computer or laptop) operated by a user 92, a server 94, and a database 95. The communication according to FIG. 5 can, for example, implement the method from FIG. 3.

In the example shown, the server 94 implements the logic for determining the diagnostic stress profile (box 5025) and for determining the health status (box 5055). The server 94 can provide a corresponding service for a variety of test benches.

For example, the server 94 may be connected to the user terminal 93 via the Internet and the user terminal 93 may be connected to the test bench 91 via a local network connection. The test stand 91 can be connected to a BMS of the traction battery of the electric vehicle 90 via a diagnostic connection, for example via a vehicle bus system.

By using the test bench 91 it is possible to specify a precisely specified diagnostic stress profile. In real traffic, only indirect specifications would be possible (e.g., standstill at certain points, specification of target speeds).

First, the setup 5005 (initialization) of a diagnostic connection between the test bench 91 and the user terminal 93 occurs when the motor vehicle 90 is connected to the test bench 91 and when a corresponding diagnostic protocol is initiated by the user 92 at the user terminal 93. For example, the test bench 91 can exchange data with a battery management system of the traction battery of the motor vehicle 90 via a vehicle bus system. As part of the setup 5005, status data 81 and type data 82 can be transmitted to the user terminal 93. The type data could also be entered, at least in part, by the user 92 at the user terminal 93. For example, the user selects the vehicle model including battery type and size.

One or more boundary conditions for the state data 81 can then be determined in box 5006, for example based on the type data 82. It can be checked whether the state of the traction battery is compatible with the one or more boundary conditions.

For example, it could be checked whether a certain minimum state of charge or a certain maximum state of charge is exceeded or not reached. Such a minimum state of charge or maximum state of charge can be selected differently depending on the battery type. It could be checked whether the operating temperature of the battery is within a certain predefined range. It could be checked whether a predefined minimum rest period has been observed. Using box 5006, a preliminary check can be carried out as to whether the state of the traction battery of the electric vehicle 90 is fundamentally suitable in order to enable a quick assessment of the state of health.

If the check in box 5006 is successful, a request 5010 can then be sent to server 94. The request 5010 contains the status data 81 and the type data 82.

While in the illustrated example of FIG. 5, the status data 81 and the type data 82 are transmitted from the user terminal 93 to the server 94, it would also generally be possible for the status data 81 and the type data 82 to be transmitted directly from the test bench 91 to the server 94.

The server 94 can then send a corresponding request 5015 to the database 95. Optionally, it is possible that this request 5015 comprises the status data 81 and/or the type data 82.

A message 5020 is then transmitted from the database 95 to the server 94, which is indicative of one or more references. For example, predefined dependencies, as discussed above in connection with FIG. 4 and TABs. 3 and 4, could be transferred.

The diagnostic stress profile can then be determined in box 5025. References according to message 5020 can be taken into account.

The diagnostic stress profile can then be transmitted to the test bench 91 with a message 5026, for example directly from the server 94 or via the user terminal 93.

The test bench 91 then applies the diagnostic stress profile over a period of time, which is indicated by reference numeral 5028 in FIG. 5. It is possible for the test bench 91 to transmit measurement data to the server 94 several times in corresponding messages 5030.

The measurement data is indicative of a voltage profile and a current profile of the stress process of the traction battery of the vehicle 90, which is caused by the diagnostic stress profile.

FIG. 5 shows a scenario in which the measurement data is transmitted to the server 94 before the diagnostic stress profile is completed. This makes it possible to optionally monitor the measurement data in box 5035 during the application of the diagnostic stress profile and to adjust the diagnostic stress profile based on the monitoring of the measurement data by means of a corresponding message 5040. For example, based on the “preliminary” measurement data, it may become apparent that further operating blocks of the stress profile are required in order to make a reliable estimate of the state of health. The diagnostic stress profile could then be extended ad hoc by sending message 5040. The monitoring of the measurement data can comprise, in particular, monitoring a deviation of voltage values of the voltage profile between different battery cells of the traction battery. Such techniques are based on the knowledge that a deviation between the voltage profiles of the different battery cells can be indicative of a different degree of aging of the different battery cells. In such scenarios, it is typically necessary to collect more differentiated measurement data, which enables a breakdown of the state of health for the different battery cells of the battery. For example, a corresponding operating block of the diagnostic stress profile, which enables further differentiation between different battery cells, could be optionally activated if the measurement data indicates a corresponding deviation between voltage values for different battery cells.

In different variants, it would be conceivable that the estimation algorithm for determining the state of health estimation of the traction battery of the vehicle 90 is permanently stored in the server 94. This means that the same estimation algorithm can be used regardless of the type of battery and/or regardless of the state of the battery.

In other examples, however, it would also be conceivable for an estimation algorithm to be selected from several candidate estimation algorithms, for example depending on the type of data and/or the status data. In the scenario of FIG. 5, the server 94 sends a corresponding request 5045 to the database 95. The database 95 then sends a message 5050 indexing the specific estimation algorithm. For example, request 5045 could include type data 82.

Such techniques are based on the realization that sometimes certain preferred types of estimation algorithms are not available for all types of batteries, e.g., because they have not yet been suitably parameterized (see FIG. 2: Box 6005). For example, a machine-learned model could only be available for some battery types because no corresponding training has yet taken place. If no specially signed machine-learned model is available, a general estimation algorithm can be used, which in principle may provide a lower accuracy.

The state of health estimation is then determined in box 5055, using the appropriate estimation algorithm. Multiple estimation algorithms could also be combined. The results could then be compared. This can increase accuracy.

The result of the estimation can be transmitted to the user terminal 93 with a message 5060. The result of the diagnosis can be output to the user 94.

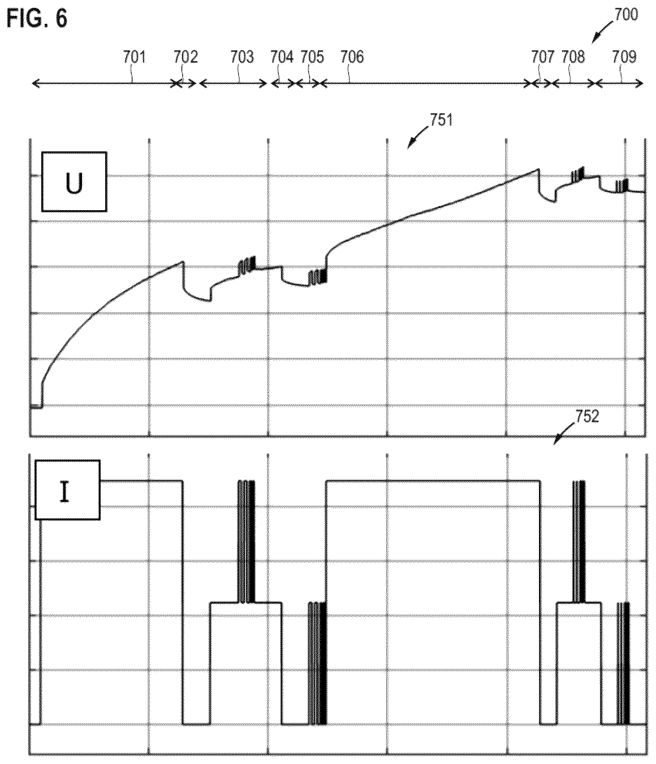

FIG. 6 illustrates aspects related to an exemplary diagnostic stress profile 700. The diagnostic stress profile 700 comprises several operating blocks 701-709 (see TAB. 1). During operation block 701, a constant current flow is used to charge the battery. This is followed by a rest phase in operating block 702. In operation block 703, variable current flow is used. Another rest phase follows in block 704. Current pulses are then applied in operation block 705. Blocks 706-709 then correspond to a repetition of blocks 701-705.

In FIG. 6 also shows corresponding measurement data for the voltage profile 751 and the current profile 752.

In summary, the techniques described above enable the collection of measurement data to estimate a state of health within a short period of time. Techniques have been described that can be carried out in workshops, roadworthiness centers during repairs or during the suitability test. Only a single partial charging process is required. It is possible to ensure comparable test conditions during data recording (not possible in driving mode or only with great effort using a chassis dynamometer).

Obviously, the features of the embodiments and aspects of the invention described above can be combined with one another. In particular, the features can be used not only in the described combinations, but also in other combinations or on their own, without leaving the field of the invention.

For example, techniques have been described above in which a diagnostic stress profile is determined based on status data and based on type data of a traction battery. Alternatively or additionally, other or further decision criteria could also be taken into account when determining the diagnostic stress profile. For example, it would be conceivable for user input to be taken into account. For example, the user could specify a desired voltage, desired power, desired battery charge or desired battery temperature to serve as the basis for the state of health estimation. The diagnostic stress profile can then be determined in such a way that measurement data is collected at the corresponding target value. Another aspect concerns obtaining status data from the test bench. For example, the test bench could signal an ambient temperature of the motor vehicle. The ambient temperature could be taken into account when determining the diagnostic stress profile.

Techniques using a stress diagnostic profile to charge the traction battery were also described above. Accordingly, it would be possible to use a stress diagnostic profile to discharge the traction battery. Combined charging and discharging would also be conceivable. Furthermore, aspects related to determining the state of health for traction batteries of electric vehicles were described. In general, however, it would also be possible to use the corresponding technologies for other types of batteries or other application scenarios. For example, it would be conceivable to use the technologies described here for batteries in stationary energy storage systems. Even in such an application scenario, it may be desirable to interrupt normal operation only briefly, meaning to keep the diagnosis time as short as possible.

1. A computer-implemented method, the method comprising:
obtaining type data and status data of a traction battery of an electric vehicle which is connected to a test bench,
based on the type data and based on the status data, determining a diagnostic stress profile comprising several operating blocks that are associated with different stress scenarios,
activating the test bench to apply the diagnostic stress profile in order to obtain measurement data for a voltage profile and a current profile of a stress process of the traction battery, and
determining a state of health estimation of the traction battery based on the measurement data.

2. The computer-implemented method according to claim 1,
wherein determining the diagnostic stress profile comprises: selecting the multiple operational blocks from a plurality of multiple predefined operational blocks.

3. The computer-implemented method according to claim 1,
wherein determining the diagnostic stress profile comprises: determining a sequence of the multiple operating blocks.

4. The computer-implemented method according to claim 1,
wherein determining the diagnostic stress profile comprises: parameterizing one or more parameters of at least one operating block of the multiple operating blocks.

5. The computer-implemented method according to claim 4,
wherein the one or more parameters of the at least one operating block are selected from a group comprising: duration of the corresponding operating block; discharge or charge rate of a discharge or charge current; charging depth; amplitude of a current pulse.

6. The computer-implemented method according to claim 1,
wherein the diagnostic stress profile is determined based on one or more predefined dependencies between parameters of the diagnostic stress profile and the status data and/or the type data.

7. The computer-implemented method according to claim 6,
wherein the one or more predefined dependencies are determined based on reference measurements that collect the physio-chemical properties of the respective battery type.

8. The computer-implemented method according to claim 6,
wherein the estimate is determined using an estimation algorithm,
wherein the one or more predefined dependencies are determined based on training measurement data used to parameterize the estimation algorithm.

9. The computer-implemented method according to claim 6,
wherein the one or more predefined dependencies are associated with expected values for an accuracy of the health status estimate,
wherein the diagnostic stress profile is determined taking into account the expected values for the accuracy of the state of health estimation.

10. The computer-implemented method according to claim 1,
wherein the diagnostic stress profile is determined taking into account a duration of the diagnostic stress profile and/or an accuracy of the state of health estimation.

11. The computer-implemented method according to claim 10,
wherein the diagnostic stress profile is determined using an iterative numerical optimization that takes into account an objective function that penalizes longer durations of the diagnostic stress profile and penalizes lower accuracies of the state of health estimation.

12. The computer-implemented method according to claim 1, the method further comprising:
while applying the diagnostic stress profile, monitoring the measurement data and optionally adjusting a remaining part of the diagnostic stress profile based on monitoring the measurement data.

13. The computer-implemented method according to claim 12,
wherein the monitoring of the measurement data comprises monitoring a deviation of voltage values of the voltage profile between different battery cells of the traction battery.

14. The computer-implemented method according to claim 1, the method further comprising:
based on the type data, selecting an estimation algorithm from several candidate estimation algorithms,
wherein the estimate is determined using the selected estimation algorithm.

15. The computer-implemented method according to claim 1,
wherein determining the diagnostic stress profile and determining the state of health estimation is executed by a central server connected to a plurality of test benches, the plurality of test benches comprising the test bench.

16. The computer-implemented method according to claim 1, the method further comprising:
determining one or more boundary conditions for the status data and checking whether the state of the battery is compatible with the one or more boundary conditions,
wherein the one or more boundary conditions are determined based on the type data.

17. The computer-implemented method according to claim 1,
wherein the diagnostic stress profile defines a partial charge of the battery, which increases a state of charge of the battery by no more than 15 percentage points.

18. The computer-implemented method according to claim 1, the method further comprising:
obtaining additional status data of the test bench,
wherein the diagnostic stress profile is further determined based on the additional status data.

19. The computer-implemented method according to claim 1,
wherein determining the diagnostic stress profile comprises: based on a state of charge of the traction battery indicated by the state data, determining a state of charge difference of the state of charge, wherein the state of charge difference between a start and an end of the diagnostic stress profile is effected by applying the diagnostic stress profile.

20. The computer-implemented method according to claim 1,
wherein determining the diagnostic stress profile comprises: based on a state of charge and/or a temperature of the traction battery indicated by the state data, determining a duration of a charging phase of the diagnostic stress profile.

21. A computer program product comprising a non-transitory computer readable medium storing program code, wherein executing the program code by a processor causes the processor to execute the method comprising:
obtaining type data and status data of a traction battery of an electric vehicle which is connected to a test bench,
based on the type data and based on the status data, determining a diagnostic stress profile comprising several operating blocks that are associated with different stress scenarios,
activating the test bench to apply the diagnostic stress profile in order to obtain measurement data for a voltage profile and a current profile of a stress process of the traction battery, and
determining a state of health estimation of the traction battery based on the measurement data.
